(19) United States
(12) Patent Application Publication
(10) Pub. No.: US 2025/0338501 A1
(43) Pub. Date: Oct. 30, 2025

(54) SEMICONDUCTOR DEVICE HAVING A CRYSTALLINE THIN-FILM FERROELECTRIC LAYER AND METHOD OF MANUFACTURE

(71) Applicant: SK hynix Inc., Icheon-si (KR)

(72) Inventor: Won Tae KOO, Icheon-si (KR)

(21) Appl. No.: 18/917,841

(22) Filed: Oct. 16, 2024

(30) Foreign Application Priority Data
Apr. 30, 2024 (KR) 10-2024-0057662

(51) Int. Cl. H10B 51/30; H01L 29/78; H10B 51/40

(52) U.S. Cl. CPC H10B 51/30; H10B 51/40; H10D 30/701

(57) ABSTRACT

A semiconductor device includes a first interconnection line extending in a first horizontal direction; a second interconnection line extending in a second horizontal direction, the first horizontal direction and the second horizontal direction intersect each other; and a memory cell disposed between the first interconnection line and the second interconnection line. The memory cell includes a lower electrode; a crystalline ferroelectric layer on the lower electrode; and an upper electrode on the crystalline ferroelectric layer.

### CROSS-REFERENCE TO RELATED APPLICATION

This application claims priority under 35 U.S.C. § 119 (a) to Korean Patent Application No. 10-2024-0057662 filed on Apr. 30, 2024 in the Korean Intellectual Property Office, which is incorporated herein by reference in its entirety.

### BACKGROUND

### 1. Technical Field

The present disclosure relates to a semiconductor device having a crystalline thin-film ferroelectric layer and a method of manufacturing the semiconductor device having the crystalline thin-film ferroelectric layer.

### 2. Related Art

A semiconductor device with a ferroelectric layer is being studied. Because the ferroelectric layer has low on-current characteristics, the ferroelectric layer has low power consumption. However, for a cross-point structure cell size, the on-current is very low, which results in an on/off current ratio that makes it difficult to implement crystalline thin-film ferroelectric layers in semiconductor devices.

### SUMMARY

A semiconductor device includes a first interconnection line extending in a first horizontal direction; a second interconnection line extending in a second horizontal direction, the first horizontal direction and the second horizontal direction intersecting each other; and a memory cell disposed between the first interconnection line and the second interconnection line. The memory cell includes a lower electrode; a crystalline ferroelectric layer on the lower electrode; and an upper electrode on the crystalline ferroelectric layer.

A method of manufacturing a semiconductor device includes forming a lower electrode material layer; forming a crystalline thick-film ferroelectric layer over the lower electrode material layer; thinning the crystalline thick-film ferroelectric layer by performing a first atomic layer etching process to form a preliminary crystalline thin-film ferroelectric layer; forming an upper electrode material layer over the preliminary crystalline thin-film ferroelectric layer; and patterning the upper electrode material layer, the preliminary crystalline thin-film ferroelectric layer, and the lower electrode material layer by performing a patterning process to form a memory cell including a lower electrode, a crystalline thin-film ferroelectric layer, and an upper electrode.

### BRIEF DESCRIPTION OF THE DRAWINGS

FIGS. 1A and 1B are a circuit diagram and a perspective view schematically illustrating a cell array structure of a semiconductor device according to an embodiment of the present disclosure.

FIG. 2A is a circuit diagram schematically illustrating a cell array structure of a semiconductor device, and FIG. 2B is a longitudinal cross-sectional view schematically showing a unit cell of a semiconductor device.

FIGS. 3A to 3D are longitudinal cross-sectional views schematically illustrating memory cells of semiconductor devices according to embodiments of the present disclosure.

FIGS. 4A to 4G are longitudinal cross-sectional views illustrating a method of forming a memory cell of a semiconductor device according to an embodiment of the present disclosure.

FIGS. 5A to 5G are longitudinal cross-sectional views illustrating a method of forming a memory cell of a semiconductor device according to an embodiment of the present disclosure.

FIGS. 6A and 6B are longitudinal cross-sectional views illustrating a method of forming a memory cell of a semiconductor device according to an embodiment of the present disclosure.

FIGS. 7A and 7B are longitudinal cross-sectional views illustrating a method of forming a memory cell of a semiconductor device according to an embodiment of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

An embodiment of the present disclosure provides a semiconductor device having a crystalline thin-film ferroelectric layer.

An embodiment of the present disclosure provides a method of manufacturing a semiconductor device having a crystalline thin-film ferroelectric layer.

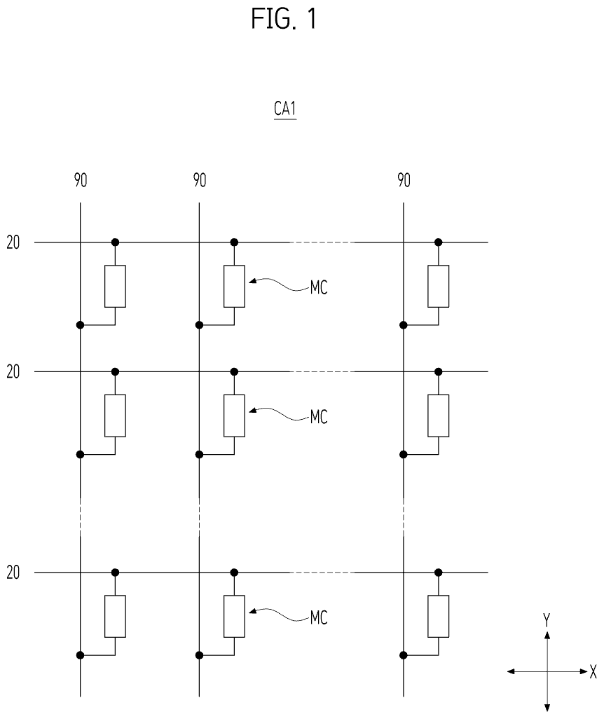

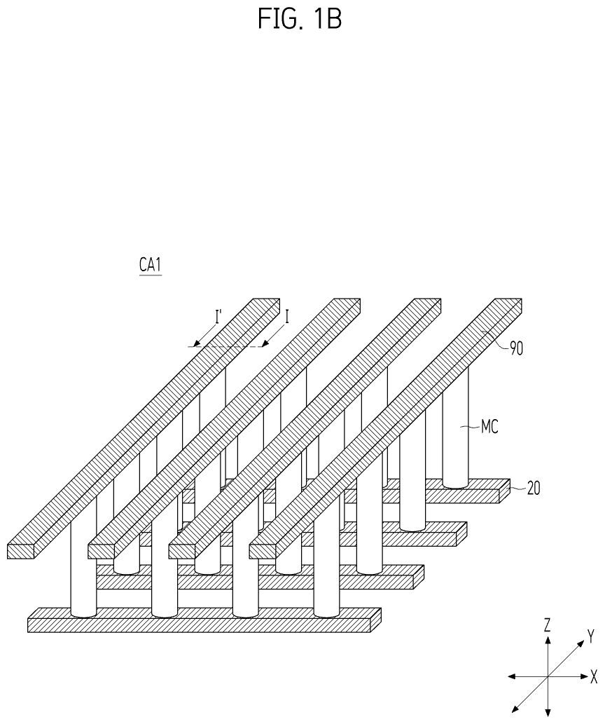

FIGS. 1A and 1B are a circuit diagram and a perspective view schematically illustrating a cell array structure of a semiconductor device according to an embodiment of the present disclosure.

Referring to FIGS. 1A and 1B, a cell array structure CA1 of a semiconductor device may include first interconnection lines 20, second interconnection lines 90, and memory cells MC. The first interconnection lines 20 may extend in parallel with each other in a first horizontal direction X. In an embodiment, the first interconnection lines 20 may be word lines. The second interconnection lines 90 may extend in parallel with each other in a second horizontal direction Y. In other embodiments, the second interconnection lines 90 may be bit lines. For example, the first interconnection lines 20 may be bit lines, and the second interconnection lines 90 may be word lines. The first horizontal direction X and the second horizontal direction Y may be perpendicular to each other. The memory cells MC may be disposed at intersections of the first interconnection lines 20 and the second interconnection lines 90, respectively, from a plan view. Each of the memory cells MC may include a variable resistance element. For example, each memory cell MC may include a crystalline ferroelectric layer. Each of the memory cells MC may be a two-electrode element. For example, first electrodes of the memory cells MC may be electrically connected to the first interconnection lines 20, respectively, and second electrodes of the memory cells MC may be electrically connected to the second interconnection lines 90, respectively.

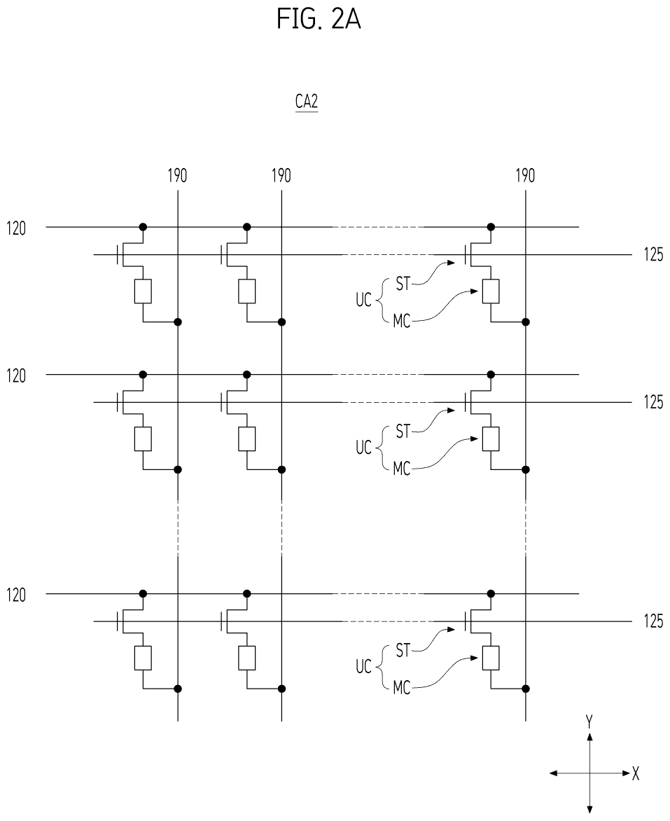

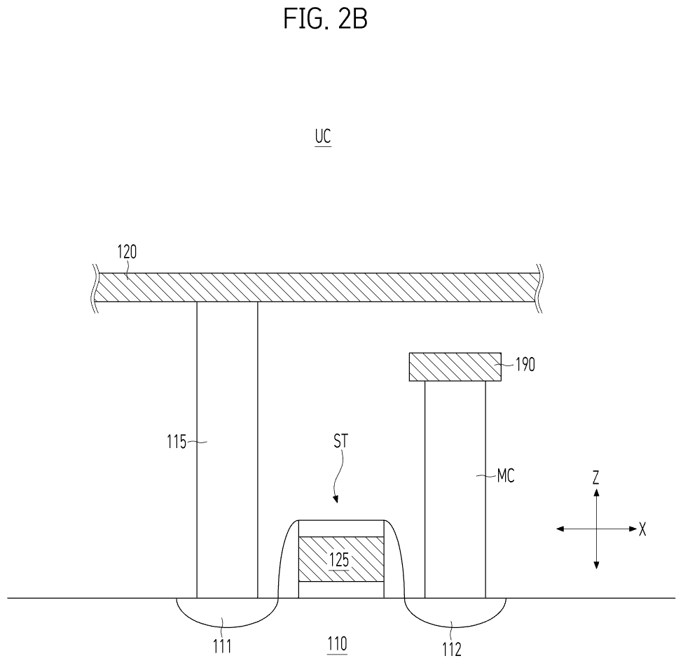

FIG. 2A is a circuit diagram schematically illustrating a cell array structure of a semiconductor device, and FIG. 2B is a longitudinal cross-sectional view schematically showing a unit cell of a semiconductor device.

Referring to FIGS. 2A and 2B, a cell array structure CA2 of a semiconductor device may include active lines 120, word lines 125, source lines 190, and unit cells UC. The active lines 120 may extend in parallel with each other in a first horizontal direction X. The source lines 190 may extend in parallel with each other in a second horizontal direction Y. The unit cells UC may be disposed at intersections of the active lines 120 and the source lines 190, respectively. Each of the unit cells UC may include a selection transistor ST and a memory cell MC. A drain electrode 111 of each of the selection transistors ST may be electrically connected to an active line 120 through an active contact plug 115. A source electrode 112 of each of the selection transistors ST may be electrically connected to the first electrode of each of the memory cells MC, respectively. A gate electrode of each of the selection transistors ST may be electrically connected to each of the word lines 125. For example, a gate electrode of each of the selection transistors ST may be each of the word lines 125, respectively. The second electrode of each of the memory cells MC may be electrically connected to each of the source lines 190, respectively. Each of the active contact plugs 115 may include a conductor, e.g., a doped polycrystalline silicon, a metal, a metal compound, a metal silicide, or a metal alloy.

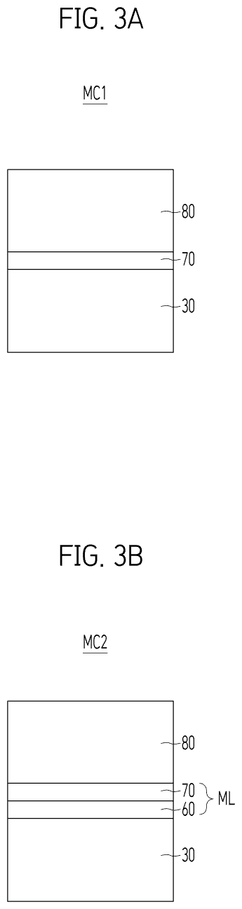

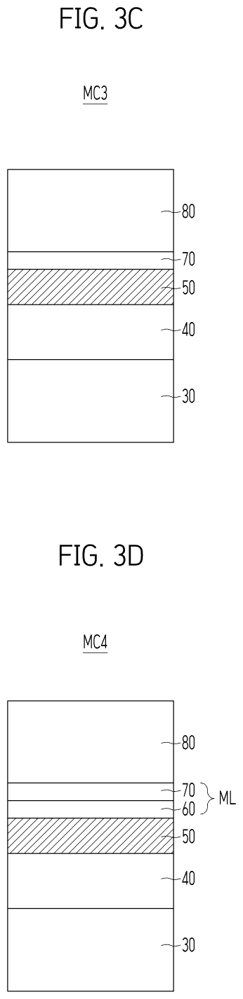

FIGS. 3A to 3D are longitudinal cross-sectional views schematically illustrating memory cells of semiconductor devices according to embodiments of the present disclosure.

Referring to FIG. 3A, a memory cell MC1 of a semiconductor device may include a lower electrode 30, a crystalline thin-film ferroelectric layer 70, and an upper electrode 80.

Both the lower electrode 30 and the upper electrode 80 may include a conductor. For example, the lower electrode 30 and the upper electrode 80 each may include at least one of a metal compound layer such as titanium nitride, a metal layer such as tungsten, a noble metal layer such as platinum, or a transition metal layer such as ruthenium. In an embodiment, the lower electrode 30 and the upper electrode 80 may include different conductors from each other for an asymmetric electric field. For example, the lower electrode 30 may include a conductor having a work function greater than that of the upper electrode 80. Specifically, the lower electrode 30 may include a titanium nitride layer, and the upper electrode 80 may include a metal layer such as tungsten. In an embodiment, the lower electrode 30 may include one of a noble metal layer such as platinum or a transition metal layer such as ruthenium, and the upper electrode 80 may include a titanium nitride layer. When the lower electrode 30 and the upper electrode 80 include a conductor having the same work function, current may be provided in the reverse direction, and thus the memory cell MC1 may malfunction. Therefore, for a unidirectional current, the lower electrode 30 and the upper electrode 80 each includes conductors having different work functions from each other.

A crystalline thin-film ferroelectric layer 70 may be disposed between the lower electrode 30 and the upper electrode 80. The crystalline thin-film ferroelectric layer 70 may include a crystalline thin-film hafnium-zirconium oxide (HZO) layer. For example, the crystalline thin-film ferroelectric layer 70 may have equal to or less than five atomic layers. The crystalline thin-film ferroelectric layer 70 may have a vertical thickness of about 2 nm or less.

An amorphous thin-film ferroelectric layer may have a relatively narrower and longer current path than the crystalline thin-film ferroelectric layer 70 due to an irregular atomic bonding structure. Thus, an amorphous thin-film ferroelectric layer may have relatively lower on-current characteristics than the crystalline thin-film ferroelectric layer 70. The crystalline thin-film ferroelectric layer 70 may have a shorter and wider current path than the amorphous thin-film ferroelectric layer due to a regular atomic bonding structure in a thin vertical thickness. Accordingly, the crystalline thin-film ferroelectric layer 70 may have higher on-current characteristics than an amorphous thin-film ferroelectric layer. For example, the crystalline thin-film ferroelectric layer 70 may exhibit an on-current in units of microamperes (μA). In addition, the crystalline thin-film ferroelectric layer 70 may exhibit off-current characteristics in units of nanoamperes (nA). An amorphous thin-film ferroelectric layer may exhibit an on/off current gain characteristics that differs in ranges from several times to several tens of times, but the crystalline thin-film ferroelectric layer 70 may exhibit an on/off current gain characteristic that differs in ranges of a thousand times or more. That is, the memory cell MC1 having the crystalline thin-film ferroelectric layer 70 may exhibit low power consumption, high-speed operation, and excellent data development characteristics.

Referring to FIG. 3B, a memory cell MC2 of a semiconductor device according to an embodiment of the present disclosure may include a lower electrode 30, a crystalline thin-film interfacial insulating layer 60, a crystalline thin-film ferroelectric layer 70, and an upper electrode 80. For example, compared to a memory cell MC1 of FIG. 3A, the memory cell MC2 may further include the crystalline thin-film interfacial insulating layer 60 disposed between the lower electrode 30 and the crystalline thin-film ferroelectric layer 70. The crystalline thin-film interfacial insulating layer 60 may include at least one of a crystalline thin-film silicon oxide layer, a crystalline thin-film hafnium oxide layer, a crystalline thin-film zirconium oxide layer, a crystalline thin-film titanium oxide layer, and other crystalline thin-film metal oxide layers. The crystalline thin-film interfacial insulating layer 60 may have equal to or less than five atomic layers. The crystalline thin-film interfacial insulating layer 60 may have a vertical thickness of about 2 nm or less. The crystalline thin-film interfacial insulating layer 60 may have asymmetric an electric field that is applied to the crystalline thin-film ferroelectric layer 70. Due to the asymmetric electric field, a current may be provided in the memory cell MC2 only in one direction. Therefore, in an embodiment, the lower electrode 30 and the upper electrode 80 can include the same material because of the crystalline thin-film interfacial insulating layer 60. Any elements not described will be understood with reference to FIG. 3A. While the lower electrode 30 and the upper electrode 80 of the memory cell MC1 of FIG. 3A must have conductors with different work functions, instead the lower electrode 30 and the upper electrode 80 of the memory cell MC2 of FIG. 3B can include conductors having the same work function. That is, in the embodiment, the lower electrode 30 and the upper electrode 80 may include the same material.

Referring to FIG. 3C, a memory cell MC3 of a semiconductor device may include a lower electrode 30, a selection element layer 40, a middle electrode 50, a crystalline thin-film ferroelectric layer 70, and an upper electrode 80.

The selection element layer 40 may include an insulating layer doped with at least one of arsenic (As) or germanium (Ge). The insulating layer of the selection element layer 40 may include at least one of silicon oxide layer, silicon nitride layer, or silicon oxide layer. For example, the selection element layer 40 may include at least one of an arsenic-doped silicon oxide layer, an arsenic-doped silicon nitride layer, an arsenic-doped silicon oxy-nitride layer, a germanium-doped silicon oxide layer, a germanium-doped silicon nitride layer, a germanium-doped silicon oxy-nitride layer, an arsenic/germanium-doped silicon oxide layer, an arsenic/germanium-doped silicon nitride layer, or an arsenic/germanium-doped silicon oxynitride layer.

The middle electrode 50 may include a metal nitride layer such as titanium nitride. In an embodiment, the middle electrode 50 may include at least one of a carbon layer, a carbon-containing metal layer, a carbon-containing metal compound layer, a carbon-containing metal alloy layer, or a carbon-containing metal silicide layer. The elements not described will be understood with reference to FIG. 3A. Because an asymmetric electric field is formed between the selection element layer 40 and the middle electrode 50, the lower electrode 30 and the upper electrode 80 can include the same material.

Referring to FIG. 3D, a semiconductor memory cell MC4 according to an embodiment of the present disclosure may include a lower electrode 30, a selection element layer 40, a middle electrode 50, a crystalline thin-film interfacial insulating layer 60, a crystalline thin-film ferroelectric layer 70, and an upper electrode 80. For example, the memory cell MC4 may further include the crystalline thin-film interfacial insulating layer 60 disposed between the middle electrode 50 and the crystalline thin-film ferroelectric layer 70 when compared to the memory cell MC3 described with reference to FIG. 3C. The elements not described will be understood with reference to FIGS. 3A to 3C.

Referring to FIGS. 3C and 3D, when the memory cells MC3 and MC4 include selection element layer 40, the selection transistor ST of FIG. 2B may be omitted from the unit cell.

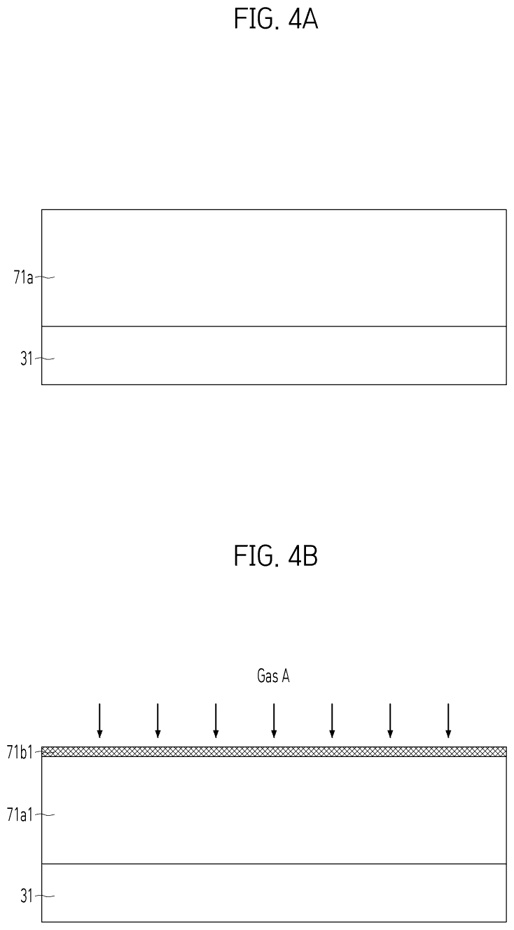

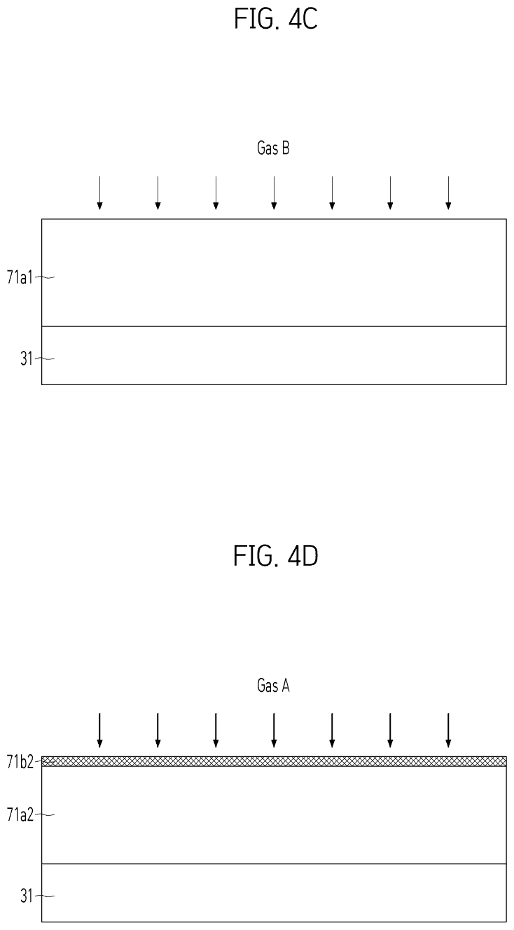

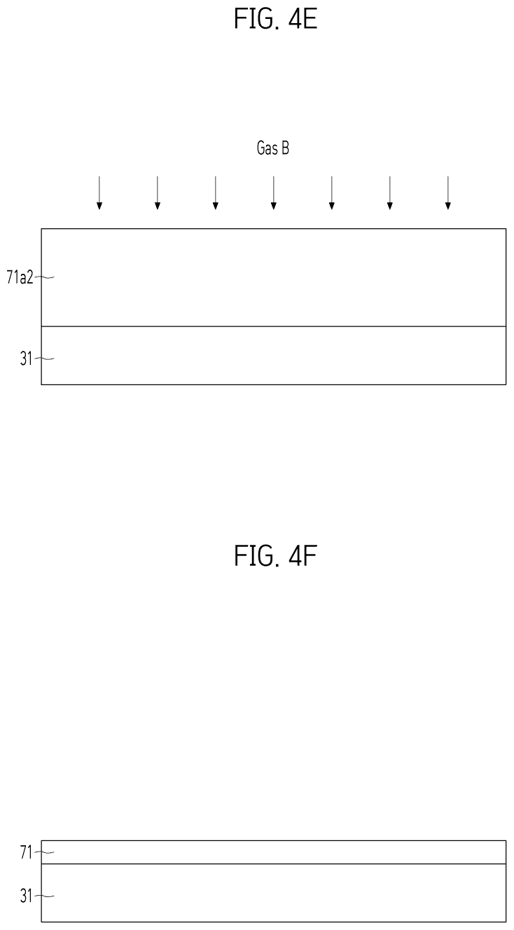

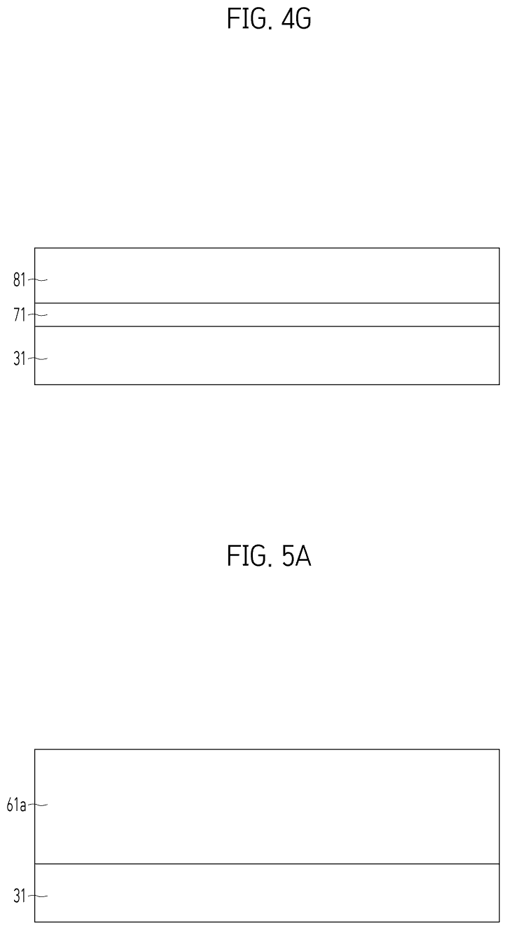

FIGS. 4A to 4G are longitudinal cross-sectional views illustrating a method of forming a memory cell of a semiconductor device according to an embodiment of the present disclosure.

Referring to FIG. 4A, a method of forming a memory cell MC1 of a semiconductor device according to an embodiment of the present disclosure may include forming a lower electrode material layer 31 and forming a crystalline thick-film ferroelectric layer 71a on the lower electrode material layer 31. Forming the lower electrode material layer 31 may include performing a deposition process, e.g., a chemical vapor deposition (CVD) process or a physical vapor deposition (PVD) process to form at least one of a titanium nitride layer, a noble metal layer, or a transition metal layer. For example, the noble metal layer may include a platinum (Pt) layer or a gold (Ag) layer. The transition metal layer may include a ruthenium (Ru) layer. Forming the crystalline thick-film ferroelectric layer 71a may include forming a crystalline thick-film hafnium zirconium oxide (HfZrO) layer by performing an atomic layer deposition (ALD) process. The crystalline thick-film ferroelectric layer 71a may have a vertical thickness sufficient to allow crystallization. It is known that it is difficult to form a crystalline ferroelectric layer with a vertical thickness of less than 5 nm. Therefore, the crystalline thick-film ferroelectric layer 71a may have a vertical thickness of about 5 nm or more. Because one layer of a crystalline ferroelectric layer may be about 0.5 nm, the crystalline thick-film ferroelectric layer 71a may be formed by repeatedly performing atomic layer deposition processes of about 10 or more times to create a stack of layers. That is, for example, the crystalline thick-film ferroelectric layer 71a may have 10 or more atomic layers. In an embodiment, the crystalline thick-film ferroelectric layer 71a may be formed by performing a deposition process, e.g., a chemical vapor deposition (CVD) process and an annealing process.

Referring to FIG. 4B, the method may further include forming a first modified ferroelectric layer 71b1 by partially modifying an upper part of the crystalline thick-film ferroelectric layer 71a. For example, one atomic layer of the uppermost layers of the crystalline thick-film ferroelectric layer 71a may be modified and changed into a first modified ferroelectric layer 71b1. The first modified ferroelectric layer 71b1 may have a vertical thickness of one atomic layer. Thus, the first modified ferroelectric layer 71b1 may have a vertical thickness of about 0.5 nm. As a result, the crystalline thick-film ferroelectric layer 71a may be thinned to form a first thinned crystalline thick-film ferroelectric layer 71a1. Forming the first modified ferroelectric layer 71b1 may include performing a first modification process. The first modification process may include chemically modifying one atomic layer of the crystalline thick-film ferroelectric layer 71a using a modified gas Gas A including at least one of halogen elements F, Cl, Br, or I. After performing the first modification process, a first pre-purging process may be performed. The first pre-purging process may be performed using at least one of inert gases, e.g., nitrogen (N), helium (He), and argon (Ar).

Referring to FIG. 4C, the method may further include removing the first modified ferroelectric layer 71b1. The first modified ferroelectric layer 71b1 may be removed by performing a first etching process using an etching gas (Gas B). The first thinned crystalline thick-film ferroelectric layer 71a1 may remain after the first etching process. After performing the first etching process, a first post-purging process may be performed. The first post-purging process may be performed using at least one of inert gases, e.g., nitrogen (N), helium (He), and argon (Ar).

Referring to FIG. 4D, the method may further include forming a second modified ferroelectric layer 71b2 by partially modifying an upper part of the first thinned crystalline thick-film ferroelectric layer 71a1. For example, one atomic layer of the uppermost layers of the first thinned crystalline thick-film ferroelectric layer 71a1 may be modified into a second modified ferroelectric layer 71b2. The second modified ferroelectric layer 71b2 may also have a vertical thickness of one atomic layer. For example, the second modified ferroelectric layer 71b2 may also have a vertical thickness of about 0.5 nm. As a result, the first thinned crystalline thick-film ferroelectric layer 71a1 may be thinned to form the second thinned crystalline thick-film ferroelectric layer 71a2. Forming the second modified ferroelectric layer 71b2 may include performing a second modification process. The second modification process may include chemically modifying one atomic layer of the first thinned crystalline thick-film ferroelectric layer 71a1 using the modified gas Gas A including at least one of halogen elements F, Cl, Br, or I. After performing the second modification process, a second pre-purging process may be performed.

Referring to FIG. 4E, the method may further include removing the second modified ferroelectric layer 71b2. The second modified ferroelectric layer 71b2 may be removed by performing a second etching process using the etching gas Gas B. The second thinned crystalline thick-film ferroelectric layer 71a2 may remain. After performing the second etching process, a second post-purge process may be performed.

Referring to FIG. 4F, the method may further include forming a preliminary crystalline thin-film ferroelectric layer 71 by repeatedly performing the modification process, the pre-purging process, the etching process, and the post-purging process described with reference to FIGS. 4B to 4E. The preliminary crystalline thin-film ferroelectric layer 71 may have equal to or less than five atomic layers. For example, the preliminary crystalline thin-film ferroelectric layer 71 may have a vertical thickness of about 2 nm or less.

Referring to FIGS. 4B to 4F, the preliminary crystalline thin-film ferroelectric layer 71 may be formed by performing an atomic layer etching process. For example, one modification process, one pre-purging process, one etching process, and one post-purging process can form one cycle of the atomic layer etching process. As described above, repeated cycles of the atomic layer etching process may be performed to form the preliminary crystalline thin-film ferroelectric layer 71.

Referring to FIG. 4G, the method may further include forming an upper electrode material layer 81 on the preliminary crystalline thin-film ferroelectric layer 71. The upper electrode material layer 81 may be formed by performing a deposition process, e.g., a CVD process or a PVD process. The upper electrode material layer 81 may include forming at least one of a titanium nitride layer, a noble metal layer, or a transition metal layer. The upper electrode material layer 81 may include a material layer different from the lower electrode material layer 31. For example, the work function of the upper electrode material layer 81 may be lower than the work function of the lower electrode material layer 31. In an embodiment, when the lower electrode material layer 31 includes a titanium nitride layer, the upper electrode material layer 81 may include a tungsten layer. In another embodiment, when the lower electrode material layer 31 includes a platinum layer, the upper electrode material layer 81 may include a titanium nitride layer.

Thereafter, referring to FIG. 3A, the method may further include forming a memory cell MC1 including the lower electrode 30, the crystalline thin-film ferroelectric layer 70, and the upper electrode 80 by performing a patterning process to pattern the upper electrode material layer 81, the preliminary crystalline thin-film ferroelectric layer 71, and the lower electrode material layer 31.

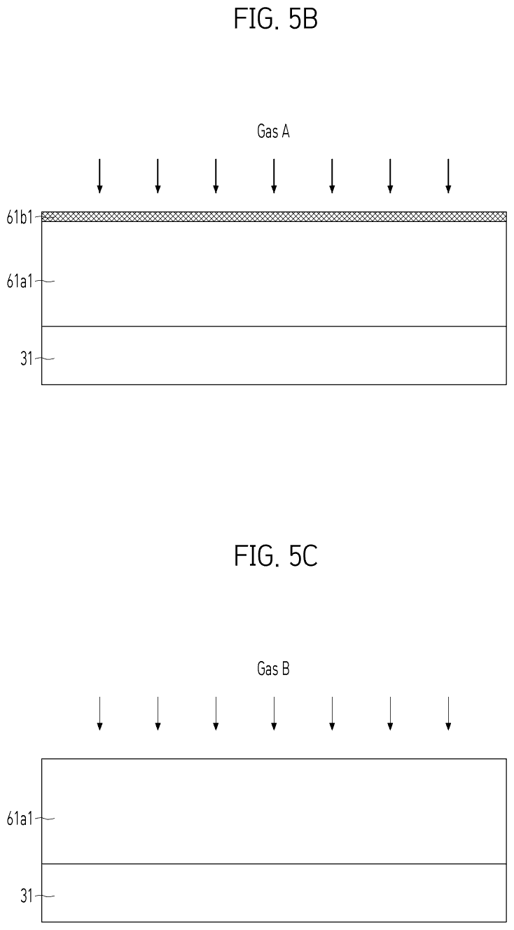

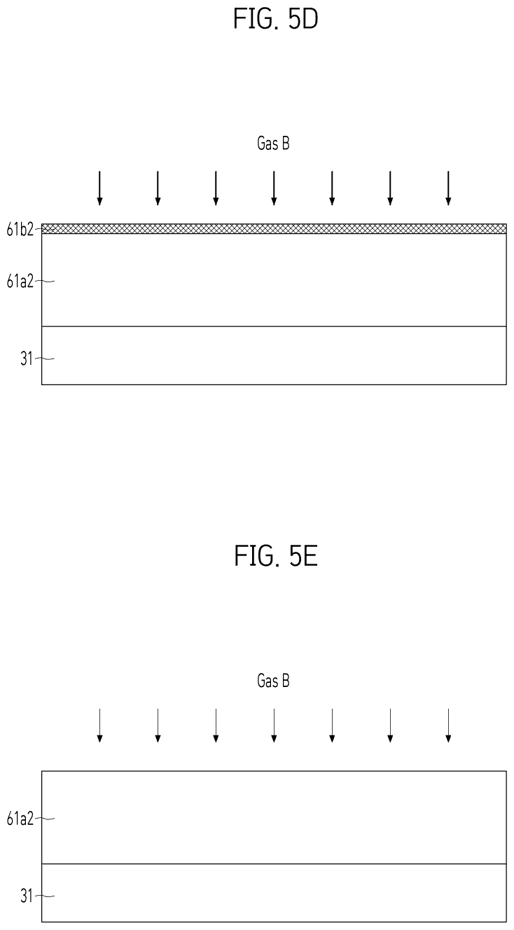

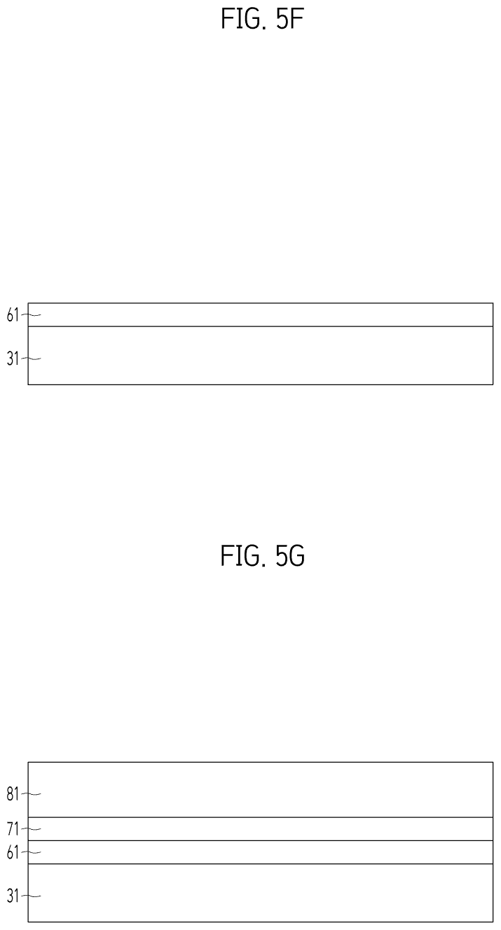

FIGS. 5A to 5G are longitudinal cross-sectional views illustrating a method of forming a memory cell of a semiconductor device according to an embodiment of the present disclosure.

Referring to FIG. 5A, a method of forming a semiconductor memory cell MC2 may include forming a lower electrode material layer 31 and forming a crystalline thick-film interfacial insulating layer 61a on the lower electrode material layer 31. Forming the crystalline thick-film interfacial insulating layer 61a may include forming one of a crystalline thick-film silicon oxide (SiO₂) layer, a crystalline thick-film hafnium oxide (HfO) layer, a crystalline thick-film zirconium oxide (ZrO) layer, or a crystalline thick-film titanium oxide (TiO₂) layer by performing an atomic layer deposition (ALD) process. The crystalline thick-film interfacial insulating layer 61a may have a vertical thickness sufficient to allow crystallization. It is known that it is difficult to form a crystalline interfacial insulating layer with a vertical thickness of less than 5 nm. Therefore, the crystalline thick-film interfacial insulating layer 61a may have a vertical thickness of about 5 nm or more. Since the thickness of one layer of the crystalline interfacial insulating layer is about 0.5 nm, the crystalline thick-film interfacial insulating layer 61a may be formed by repeatedly performing an atomic layer deposition process of about 10 times or more to create a stack of layers. That is, for example, the crystalline thick-film interfacial insulating layer 61a may have at least 10 atomic layers. In an embodiment, the crystalline thick-film interfacial insulating layer 61a may be formed by performing a deposition process such as a chemical vapor deposition (CVD) process and an annealing process.

Referring to FIG. 5B, the method may further include forming a first modified interfacial insulating layer 61b1 by partially modifying an upper part of the crystalline thick-film interfacial insulating layer 61a. For example, one atomic layer on the upper part of the crystalline thick-film interfacial insulating layer 61a may be modified and changed into a first modified interfacial insulating layer 61b1. The first modified interfacial insulating layer 61b1 may have a vertical thickness of one atomic layer. Thus, the first modified interfacial insulating layer 61b1 may have a vertical thickness of about 0.5 nm. As a result, the crystalline thick-film interfacial insulating layer 61a may be thinned to form the first thinned crystalline thick-film interfacial insulating layer 61a1. Forming the first modified interfacial insulating layer 61b1 may include performing a first modified process. The first modification process may include chemically modifying one atomic layer of the crystalline thick-film interfacial insulating layer 61a using a modifying gas Gas A including at least one of halogen elements F, Cl, Br, and I. A first pre-purging process may be performed after performing the first modification process. The first pre-purging process may be performed using at least one inert gas, e.g., nitrogen, helium, or argon.

Referring to FIG. 5C, the method may further include removing the first modified interfacial insulating layer 61b1. The first modified interfacial insulating layer 61b1 may be removed by performing a first etching process using an etching gas Gas B. The first thinned crystalline thick-film interfacial insulating layer 61a1 may remain after the first etching process. A first post-purge process may be performed after the performing first etching process. The first post-purging process may be performed using at least one inert gas, e.g., nitrogen, helium, and argon.

Referring to FIG. 5D, the method may further include forming a second modified interfacial insulating layer 61b2 by partially modifying an upper part of the first thinned crystalline thick-film interfacial insulating layer 61a1. For example, one atomic layer of the uppermost layers of the first thinned crystalline thick-film interfacial insulating layer 61a1 may be modified into a second modified interfacial insulating layer 61b2. The second modified interfacial insulating layer 61b2 may also have the vertical thickness of one atomic layer. The second modified interfacial insulating layer 61b2 may also have the vertical thickness of about 0.5 nm. As a result, the first thinned crystalline thick-film interfacial insulating layer 61a1 may be thinned to form the second thinned crystalline thick-film interfacial insulating layer 61a2. Forming the second modified interfacial insulating layer 61b2 may include performing a second modified process. The second modification process may include chemically modifying one atomic layer of the first thinned crystalline thick-film interfacial insulating layer 61a1 using the modified gas Gas A including at least one of halogen elements F, Cl, Br, and I. A second pre-purging process may be performed after the second modification process.

Referring to FIG. 5E, the method may further include removing the second modified interfacial insulating layer 61b2. The second modified interfacial insulating layer 61b2 may be removed by performing a second etching process using an etching gas Gas B. The second thinned crystalline thick-film interfacial insulating layer 61a2 may remain. A second post-purge process may be performed after the second etching process.

Referring to FIG. 5F, the method may further include forming a preliminary crystalline thin-film interfacial insulating layer 61 by repeatedly performing the modified processes, pre-purge processes, etching processes, and post-purge processes described with reference to FIGS. 5B to 5E. The preliminary crystalline thin-film interfacial insulating layer 61 may have five or less atomic layers. For example, the preliminary crystalline thin-film interfacial insulating layer 61 may have a vertical thickness of about 2 nm or less.

Referring to FIGS. 5B to 5F, the preliminary crystalline thin-film interfacial insulating layer 61 may be formed by performing an atomic layer etching process. For example, one modification process, one pre-purging process, one etching process, and one post-purging process can form one cycle of one atomic layer etching process. As described above, repeated cycles of the atomic layer etching process may be performed to form the preliminary crystalline thin-film interfacial insulating layer 61.

Referring to FIG. 5G, the method may further include forming a preliminary crystalline thin-film ferroelectric layer 71 and an upper electrode material layer 81 on the preliminary crystalline thin-film interfacial insulating layer 61. The preliminary crystalline thin-film ferroelectric layer 71 and the upper electrode material layer 81 may be formed by performing the processes described above with reference to FIGS. 4A to 4G.

Thereafter, referring to FIG. 3B, the method may further include patterning the upper electrode material layer 81, the preliminary crystalline thin-film ferroelectric layer 71, the preliminary crystalline thin-film interfacial insulating layer 61, and the lower electrode material layer 31 by performing a patterning process to form a memory cell MC2 including a lower electrode 30, a crystalline thin-film interfacial insulating layer 60, a crystalline thin-film ferroelectric layer 70, and an upper electrode 80.

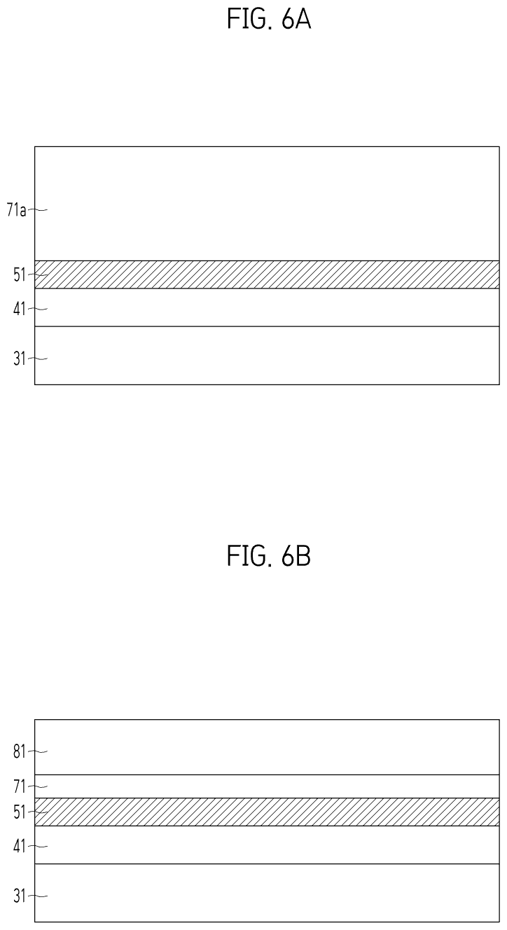

FIGS. 6A and 6B are longitudinal cross-sectional views illustrating a method of forming a memory cell of a semiconductor device according to an embodiment of the present disclosure.

Referring to FIG. 6A, a method of forming a semiconductor memory cell MC3 may include forming a lower electrode material layer 31, forming a selection element material layer 41 on the lower electrode material layer 31, forming a middle electrode material layer 51 on the selection element material layer 41, and forming a crystalline thick-film ferroelectric layer 71a on the middle electrode material layer 51.

The selection element material layer 41 may be formed by performing a deposition process such as a CVD process and an ion doping process. The ion doping process may include a plasma doping process or an ion implant process. For example, forming the selection element material layer 41 may include forming a base insulating layer including at least one of silicon oxide or silicon nitride, and doping at least one of arsenic (As) or germanium (Ge) into the base insulating layer.

The middle electrode material layer 51 may include a metal compound layer, e.g., a titanium nitride layer or a carbon layer.

Forming the lower electrode material layer 31 and the crystalline thick-film ferroelectric layer 71a may be understood to be as described above with reference to FIG. 4A.

Referring to FIG. 6B, the method may further include forming a preliminary crystalline thin-film ferroelectric layer 71 and an upper electrode material layer 81 by performing the processes described above with reference to FIGS. 4B to 4G.

Thereafter, referring to FIG. 3C, the method may further include patterning the upper electrode material layer 81, the preliminary crystalline thin-film ferroelectric layer 71, the middle electrode material layer 51, the selection element material layer 41, and the lower electrode material layer 31 by performing a patterning process to form a memory cell MC3 including a lower electrode 30, a selection element layer 40, a middle electrode 50, a crystalline thin-film ferroelectric layer 70, and an upper electrode 80.

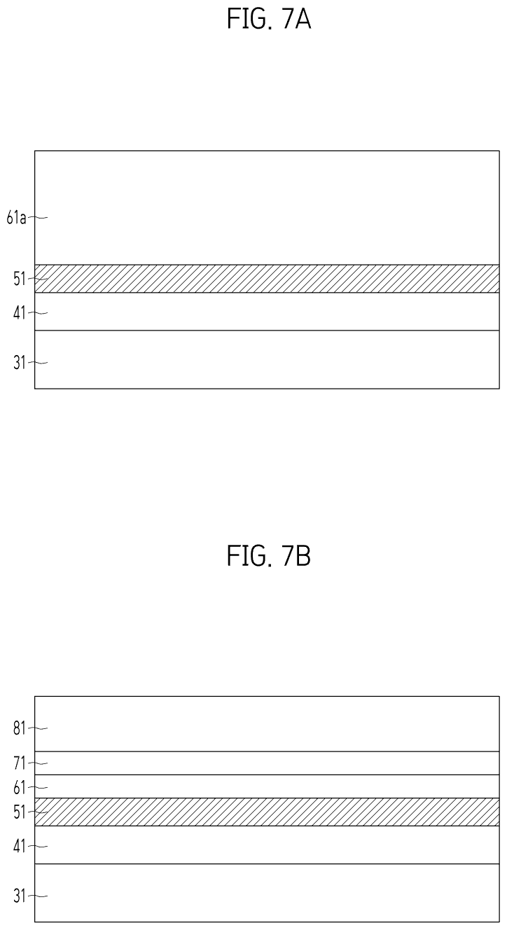

FIGS. 7A and 7B are longitudinal cross-sectional views illustrating a method of forming a memory cell of a semiconductor device according to an embodiment of the present disclosure.

Referring to FIG. 7A, a method of forming a memory cell MC4 of a semiconductor device may include forming a lower electrode material layer 31, forming a selection element material layer 41 on the lower electrode material layer 31, forming a middle electrode material layer 51 on the selection element material layer 41, and forming a crystalline thick-film interfacial insulating layer 61a on the middle electrode material layer 51.

The selection element material layer 41 may be formed by performing a deposition process such as a CVD process and an ion doping process. As described above, the ion doping process may include a plasma doping process or an ion impedance process. For example, forming the selection element material layer 41 may include forming a base insulating layer including at least one of silicon oxide or silicon nitride, and doping at least one of arsenic (As) or germanium (Ge) into the base insulating layer.

The middle electrode material layer 51 may include a metal compound layer, e.g., a titanium nitride layer or a carbon layer.

Forming the lower electrode material layer 31 and the crystalline thick-film interfacial insulating layer 61a may be understood as described above with reference to FIG. 4A.

Referring to FIG. 7B, the method may further include forming a preliminary crystalline thin-film interfacial insulating layer 61, a preliminary crystalline thin-film ferroelectric layer 71, and an upper electrode material layer 81 by performing the processes described above with reference to FIGS. 5B to 5G.

Thereafter, referring to FIG. 3D, the method may further include patterning the upper electrode material layer 81, the preliminary crystalline thin-film ferroelectric layer 71, the preliminary crystalline thin-film interfacial insulating layer 61, the middle electrode material layer 51, the selection element material layer 41, and the lower electrode material layer 31 by performing a patterning process to form a memory cell MC4 with a lower electrode 30, a selection element layer 40, a middle electrode 50, a crystalline thin-film interfacial insulating layer 60, a crystalline thin-film ferroelectric layer 70, and an upper electrode 80.

According to an embodiment of the present disclosure, the semiconductor devices each including a crystalline thin-film ferroelectric layer can have high on-current characteristics and high on/off current ratios. Accordingly, the semiconductor devices according to embodiments of the present disclosure can have low power consumption, high-speed operation, and excellent data development characteristics.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

What is claimed is:

1. A semiconductor device comprising:
a first interconnection line extending in a first direction;
a second interconnection line extending in a second direction, the first direction and the second direction intersecting each other; and
a memory cell disposed between the first interconnection line and the second interconnection line,
wherein the memory cell comprises:
a lower electrode;
a crystalline ferroelectric layer on the lower electrode; and
an upper electrode on the crystalline ferroelectric layer.

2. The semiconductor device of claim 1,
wherein the crystalline ferroelectric layer includes hafnium zirconium oxide layer.

3. The semiconductor device of claim 1, wherein:
the lower electrode has a first work function,
the upper electrode has a second work function, and
the first work function is greater than the second work function.

4. The semiconductor device of claim 1, wherein:
the lower electrode includes titanium nitride, and
the upper electrode includes tungsten.

5. The semiconductor device of claim 1, further comprising:
a crystalline interfacial insulating layer between the lower electrode and the crystalline ferroelectric layer.

6. The semiconductor device of claim 5,
wherein the crystalline interfacial insulating layer includes at least one of a crystalline silicon oxide layer, a crystalline hafnium oxide layer, and a crystalline zirconium oxide layer.

7. The semiconductor device of claim 5,
wherein a work function of the lower electrode is a same as a work function of the upper electrode.

8. The semiconductor device of claim 5,
wherein the lower electrode and the upper electrode include a same conductive material.

9. The semiconductor device of claim 5,
wherein the crystalline interfacial insulating layer has equal to or less than five atomic layers.

10. The semiconductor device of claim 5,
wherein a thickness of the crystalline interfacial insulating layer is equal to or less than 2 nm.

11. The semiconductor device of claim 1,
wherein the crystalline ferroelectric layer has equal to or less than five atomic layers.

12. The semiconductor device of claim 1,
wherein a thickness of the crystalline ferroelectric layer is equal to or less than 2 nm.

13. The semiconductor device of claim 1,
wherein the memory cell further comprises:
a selection element layer between the lower electrode and the crystalline ferroelectric layer; and
a middle electrode between the selection element layer and the crystalline ferroelectric layer.

14. The semiconductor device of claim 1, further comprising:
a selection transistor including a drain electrode electrically connected to the first interconnection line and a source electrode electrically connected to the memory cell.
